(19) United States
(12) Patent Application Publication
(10) Pub. No.: US 2026/0371862 A1
(43) Pub. Date: Nov. 19, 2026

(54) DISPLAY DEVICE

(71) Applicant: LG Display Co., Ltd., Seoul (KR)

(72) Inventors: Goeun LIM, Paju-si (KR); Saemi PARK, Paju-si (KR); Heesu BYEON, Paju-si (KR)

(73) Assignee: LG Display Co., Ltd., Seoul (KR)

(21) Appl. No.: 19/654,294

(22) Filed: Apr. 21, 2026

(30) Foreign Application Priority Data
May 15, 2025 (KR) 10-2025-0062938

(51) Int. Cl. H10K 59/124; H10K 59/80

(52) U.S. Cl. CPC H10K 59/124; H10K 59/80515

(57) ABSTRACT

A display device includes a substrate on which a first sub-pixel and a second sub-pixel are defined, a plurality of first organic insulating patterns disposed over the substrate of the first sub-pixel and having a first surface height, and a plurality of second organic insulating patterns disposed over the substrate of the second sub-pixel and having a second surface height greater than the first surface height. A first anode electrode is disposed on the plurality of first organic insulating patterns, and a second anode electrode is disposed on the plurality of second organic insulating patterns. A first light emitting layer is disposed on the first anode electrode and a second light emitting layer is disposed on the second anode electrode, and a cathode electrode is disposed on the first and second light emitting layers.

### CROSS-REFERENCE TO RELATED APPLICATION

The present application claims priority to Korean Patent Application No. 10-2025-0062938, filed May 15, 2025, the entire contents of which is incorporated herein for all purposes by this reference.

### BACKGROUND

### Technical Field

The present specification relates to a display device.

### Description of the Related Art

As the information society develops, various demands for display devices for displaying images are increasing, and various types of display devices such as liquid crystal display (LCD) devices and organic light emitting diode (OLED) display devices are utilized.

Among the display devices, there is an advantage in that the OLED displays as the self-luminous types have superior viewing angles and contrast ratios than the LCDs, and are lighter and thinner and have low power consumption because they do not require a separate backlight. In addition, there is an advantage in that the OLED displays may drive at a low direct current voltage, have a fast response speed, and especially low manufacturing costs.

Recently, demand for a display device that requires augmented reality (AR), virtual reality (VR), or equivalent ultra-high resolution using such an OLED display device is increasing.

### BRIEF SUMMARY

The present disclosure describes a display architecture that balances color output by controlling the vertical position of light emission rather than adjusting pixel area or drive current. Different sub pixels are formed on organic insulating patterns having different heights so that their anodes and light emitting layers are positioned at different elevations. Because emitters located higher produce greater perceived brightness, the blue sub pixel is positioned higher than the red and green sub pixels, improving color balance and compensating for blue degradation while maintaining the same planar pixel pitch.

The height difference is produced through a specific structural mechanism. Organic ribs are fabricated with different widths and during a rinse and spin process narrower ribs bend more than wider ribs, resulting in a lower final surface height. A single lithography process therefore forms multiple elevation levels through width dependent deformation rather than multiple etching steps or grayscale masks. Auxiliary conductive layers bridge the step so that a continuous cathode can extend across the elevation change.

Together these features provide an OLED pixel structure and fabrication method that uses deformation of patterned organic layers to set sub pixel emission heights, thereby tuning luminance distribution, extending lifetime, and supporting high resolution panels without changing emissive materials or enlarging the pixel footprint.

Further, various embodiments of the present specification are directed to providing a high-resolution display device.

Various embodiments of the present specification are also directed to providing a display device with improved color balance.

Various embodiments of the present specification are also directed to providing a low-power display device with an extended lifetime.

Technical benefits of the present specification are not limited to the above-described benefits, and other technical benefits may be inferred from the following embodiments.

According to one embodiment, there is provided a display device including a substrate on which a first sub-pixel and a second sub-pixel are defined, a plurality of first organic insulating patterns disposed over the substrate of the first sub-pixel and having a first surface height, a plurality of second organic insulating patterns disposed over the substrate of the second sub-pixel and having a second surface height, a first anode electrode on the plurality of first organic insulating patterns, and a second anode electrode on the plurality of second organic insulating patterns, wherein the second surface height is greater than the first surface height.

Detailed matters of other embodiments are included in the detailed description and accompanying drawings.

### BRIEF DESCRIPTION OF THE SEVERAL VIEWS OF THE DRAWINGS

FIG. 1 is a plan view of a display device according to one embodiment.

FIG. 2 is a cross-sectional view along line A-A’ in FIG. 1.

FIG. 3 is a cross-sectional view along line B-B’ in FIG. 1.

FIG. 4 is a schematic view illustrating an optical path in FIG. 2.

FIGS. 5-18 are cross-sectional views for each process in a method of manufacturing the display device in FIG. 1.

### DETAILED DESCRIPTION

Hereinafter, embodiments will be described with reference to the accompanying drawings. In the specification, when a certain component (or an area, a layer, a portion, etc.) is described as “on,” “connected,” or “coupled to” another component, it means that the certain component may be directly connected/coupled to another component or still another component may be disposed therebetween.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The same reference numerals indicate the same components. In addition, in the drawings, thicknesses, proportions, and dimensions of components are exaggerated for effective description of technical contents. The term “and/or” includes all one or more combinations that may be defined by the associated configurations.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms such as “first,” “second,” and the like may be used to describe various components, but the components are not limited by the terms. The terms are used only for the purpose of distinguishing one component from another. For example, a first component may be referred to as a second component, and similarly, the second component may also be referred to as the first component without departing from the scopes of various embodiments. The singular includes the plural unless the context clearly dictates otherwise.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

Terms such as “under,” “at a lower side,” “above,” and “at an upper side” are used to describe the relationship between the components illustrated in the drawings. The terms are relative concepts and are described with respect to directions marked in the drawings.

The term “rib,” as used herein for convenience, may be used to refer to each individual structure of the plurality of first organic insulating patterns and the plurality of second organic insulating patterns described in the specification. Each rib corresponds to an elongated organic insulating pattern extending upward from the substrate and forming part of the step layer on which the anode electrode is disposed. The ribs may have different widths and may bend during processing, resulting in different surface heights between the first organic insulating patterns and the second organic insulating patterns. Accordingly, any reference to ribs is intended only as a shorthand designation for the disclosed organic insulating patterns and does not introduce a different structure or material from those expressly described in the specification.

It should be understood that terms such as “includes” or “has” are intended to specify the presence of features, numbers, steps, operations, components, parts, or a combination thereof described in the specification and does not preclude the presence or addition possibility of one or more other features, numbers, steps, operations, components, parts, or combinations thereof in advance.

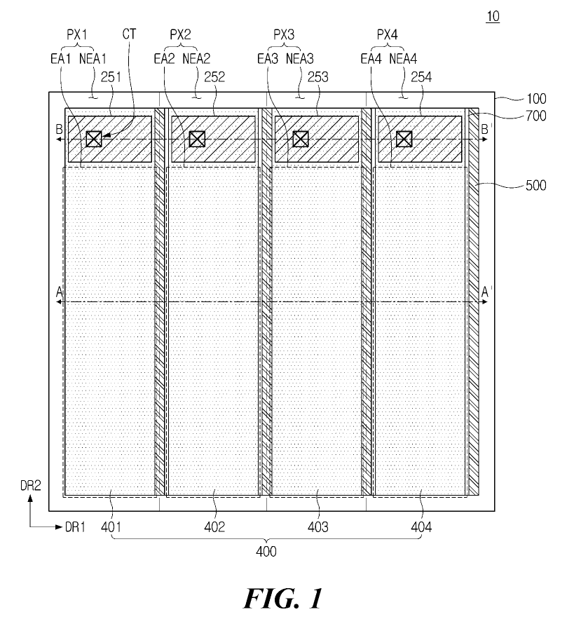

FIG. 1 is a plan view of a display device according to one embodiment.

Referring to FIG. 1, a display device 10 may include a plurality of sub-pixels PX1, PX2, PX3, and PX4. The plurality of sub-pixels PX1, PX2, PX3, and PX4 may include a first sub-pixel PX1, a second sub-pixel PX2, a third sub-pixel PX3, and a fourth sub-pixel PX4. The first sub-pixel PX1, the second sub-pixel PX2, the third sub-pixel PX3, and the fourth sub-pixel PX4 are arranged sequentially such that the second sub-pixel PX2 may be disposed adjacent to one side (e.g., the right side) of the first sub-pixel PX1, the third sub-pixel PX3 may be disposed adjacent to one side (e.g., the right side) of the second sub-pixel PX2, and the fourth sub-pixel PX4 may be disposed adjacent to one side (e.g., the right side) of the third sub-pixel PX3.

Throughout the present specification, when two sub-pixels are disposed adjacent to each other, it should be understood that no other sub-pixels are disposed between the two sub-pixels.

The first sub-pixel PX1 may be provided to emit red (R) light, the second sub-pixel PX2 may be provided to emit blue (B) light, the third sub-pixel PX3 may be provided to emit green (G) light, and the fourth sub-pixel PX4 may be provided to emit blue (B) light, but various embodiments of the present specification are not necessarily limited thereto, and for example, the sub-pixel may be provided to emit white (W) light.

In FIG. 1, the display device 10 is illustrated as including only four sub-pixels PX1, PX2, PX3, and PX4, but is not limited thereto, and may include three sub-pixels.

The first to fourth sub-pixels PX1, PX2, PX3, and PX4 may have the same size. For example, the first to fourth sub-pixels PX1, PX2, PX3, and PX4 may have the same width and the same height. Here, the width may refer to a horizontal direction (first direction DR1) based on FIG. 1, and the height may refer to a direction (second direction DR2) perpendicular to the width based on FIG. 1, but various embodiments of the present specification are not limited thereto.

The sub-pixels PX1, PX2, PX3, and PX4 may include light-emitting areas EA1, EA2, EA3, and EA4 and non-light-emitting areas NEA1, NEA2, NEA3, and NEA4, respectively. The first sub-pixel PX1 may include a first light-emitting area EA1 and a first non-light-emitting area NEA1 surrounding the first light-emitting area EA1, the second sub-pixel PX2 may include a second light-emitting area EA2 and a second non-light-emitting area NEA2 surrounding the second light-emitting area EA2, the third sub-pixel PX3 may include a third light-emitting area EA3 and a third non-light-emitting area NEA3 surrounding the third light-emitting area EA3, and the fourth sub-pixel PX4 may include a fourth light-emitting area EA4 and a fourth non-light-emitting area NEA4 surrounding the fourth light-emitting area EA4. The light-emitting areas EA1, EA2, EA3, and EA4 may be the same as areas in which anode electrodes 401, 402, 403, and 404 respectively disposed in the sub-pixels PX1, PX2, PX3, and PX4 are exposed from the banks.

The non-light-emitting areas NEA1, NEA2, NEA3, and NEA4 may be disposed at boundaries between the sub-pixels PX1, PX2, PX3, and PX4. The non-light-emitting areas NEA1, NEA2, NEA3, and NEA4 may also be disposed on upper end portions (e.g., one sides in the second direction DR2) of the light-emitting areas EA1, EA2, EA3, and EA4, respectively. The non-light-emitting areas NEA1, NEA2, NEA3, and NEA4 disposed on the upper end portions of the light-emitting areas EA1, EA2, EA3, and EA4, respectively, may be referred to as pad contact portions.

In the sub-pixels PX1, PX2, PX3, and PX4, the anode electrodes 401, 402, 403, and 404, circuit parts 251, 252, 253, and 254, insulating layers 700, auxiliary layers 500, and contact holes CT may be disposed, respectively.

An anode electrode 400 may include a first anode electrode 401 disposed in the first sub-pixel PX1, a second anode electrode 402 disposed in the second sub-pixel PX2, a third anode electrode 403 disposed in the third sub-pixel PX3, and a fourth anode electrode 404 disposed in the fourth sub-pixel PX4.

The anode electrodes 401, 402, 403, and 404 may be disposed across the light-emitting areas EA1, EA2, EA3, and EA4 and the non-light-emitting areas NEA1, NEA2, NEA3, and NEA4 of the sub-pixels PX1, PX2, PX3, and PX4, respectively. That is, the anode electrodes 401, 402, 403, and 404 may be disposed in the light-emitting areas EA1, EA2, EA3, and EA4 of the sub-pixels PX1, PX2, PX3, and PX4, respectively, one ends of the anode electrodes 401, 402, 403, and 404 may extend upward (e.g., toward one side in the second direction DR2), and portions of the extended anode electrodes 401, 402, 403, and 404 may be disposed in the non-light-emitting areas NEA1, NEA2, NEA3, and NEA4 of the sub-pixels PX1, PX2, PX3, and PX4, respectively. That is, the anode electrodes 401, 402, 403, and 404 may be disposed on the pad contact portions, respectively.

The circuit parts 251, 252, 253, and 254 may include a first circuit part 251 disposed in the first sub-pixel PX1, a second circuit part 252 disposed in the second sub-pixel PX2, a third circuit part 253 disposed in the third sub-pixel PX3, and a fourth circuit part 254 disposed in the fourth sub-pixel PX4.

The circuit parts 251, 252, 253 and 254 may be disposed in the non-light-emitting areas NEA1, NEA2, NEA3, and NEA4 of the sub-pixels PX1, PX2, PX3, and PX4, respectively, and more specifically, may be disposed on the pad contact portions. That is, the circuit parts 251, 252, 253, and 254 may be disposed in the non-light-emitting areas NEA1, NEA2, NEA3, and NEA4 respectively positioned on the one sides of the sub-pixels PX1, PX2, PX3, and PX4 in the second direction DR2.

The insulating layer 700 may be disposed on one side and the other side of the second anode electrode 402 disposed in the second sub-pixel PX2 in the first direction DR1 and disposed on one side and the other side of the fourth anode electrode 404 disposed in the fourth sub-pixel PX4 in the first direction DR1.

The insulating layer 700 may be disposed in the non-light-emitting areas NEA2 and NEA4 of the second sub-pixel PX2 and the fourth sub-pixel PX4. However, various embodiments of the present specification are not limited thereto, and for example, the insulating layer 700 may extend to one side and the other side of the second anode electrode 402 in the first direction DR1. Accordingly, the insulating layer 700 may be disposed across the first non-light-emitting area NEA1 and the second non-light-emitting area NEA2 at the boundary between the first sub-pixel PX1 and the second sub-pixel PX2, the insulating layer 700 may be disposed across the second non-light-emitting area NEA2 and the third non-light-emitting area NEA3 at the boundary between the second sub-pixel PX2 and the third sub-pixel PX3, and the insulating layer 700 may be disposed across the third non-light-emitting area NEA3 and the fourth non-light-emitting area NEA4 at the boundary between the third sub-pixel PX3 and the fourth sub-pixel PX4.

The auxiliary layers 500 may be disposed in the non-light-emitting areas NEA1, NEA2, NEA3, and NEA4 between adjacent sub-pixels PX1, PX2, PX3, and PX4. At the boundary between the first sub-pixel PX1 and the second sub-pixel PX2, the insulating layer 700 and the auxiliary layer 500 may be disposed between the first anode electrode 401 and the second anode electrode 402, and the auxiliary layer 500 may be disposed between the first anode electrode 401 and the insulating layer 700. At the boundary between the second sub-pixel PX2 and the third sub-pixel PX3, the insulating layer 700 and the auxiliary layer 500 may be disposed between the second anode electrode 402 and the third anode electrode 403, and the auxiliary layer 500 may be disposed between the third anode electrode 403 and the insulating layer 700. At the boundary between the third sub-pixel PX3 and the fourth sub-pixel PX4, the insulating layer 700 and the auxiliary layer 500 may be disposed between the third anode electrode 403 and the fourth anode electrode 404, and the auxiliary layer 500 may be disposed between the third anode electrode 403 and the insulating layer 700.

The auxiliary layer 500 may also be disposed on one side of the fourth anode electrode 404 in the first direction DR1, which is disposed in the fourth sub-pixel PX4. The insulating layer 700 and the auxiliary layer 500 may be disposed in the non-light-emitting area NEA4 on one side of the fourth anode electrode 404 in the first direction DR1, and the insulating layer 700 may be disposed between the fourth anode electrode 404 and the auxiliary layer 500.

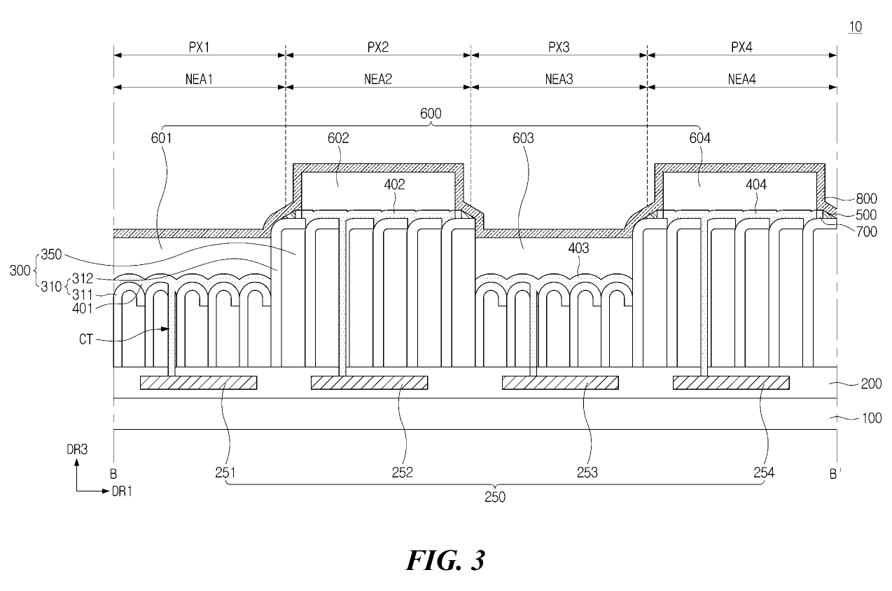

Since the insulating layer 700 and the auxiliary layer 500 may extend in the second direction DR2, the insulating layer 700 and the auxiliary layer 500 may be disposed in each of the non-light-emitting areas NEA1, NEA2, NEA3, and NEA4. However, various embodiments of the present specification are not limited thereto, and for example, the insulating layer 700 and the auxiliary layer 500 may not be disposed on the pad contact portions. The detailed descriptions thereof will be provided below with reference to FIG. 3.

The contact hole CT may be disposed in each of the first sub-pixel PX1, the second sub-pixel PX2, the third sub-pixel PX3, and the fourth sub-pixel PX4. The contact holes may be disposed in the non-light-emitting areas NEA1, NEA2, NEA3, and NEA4 of the sub-pixels PX1, PX2, PX3, and PX4, respectively, and more specifically, may be disposed in the pad contact portions. That is, the contact holes CT may be disposed in the non-light-emitting areas NEA1, NEA2, NEA3, and NEA4 positioned on the one sides of the sub-pixels PX1, PX2, PX3, and PX4, respectively.

When viewed on a plane defined by the first direction DR1 and the second direction DR2, the anode electrodes 401, 402, 403, and 404, the circuit parts 251, 252, 253, and 254, and the contact holes CT may overlap each other on the pad contact portions of the sub-pixels PX1, PX2, PX3, and PX4.

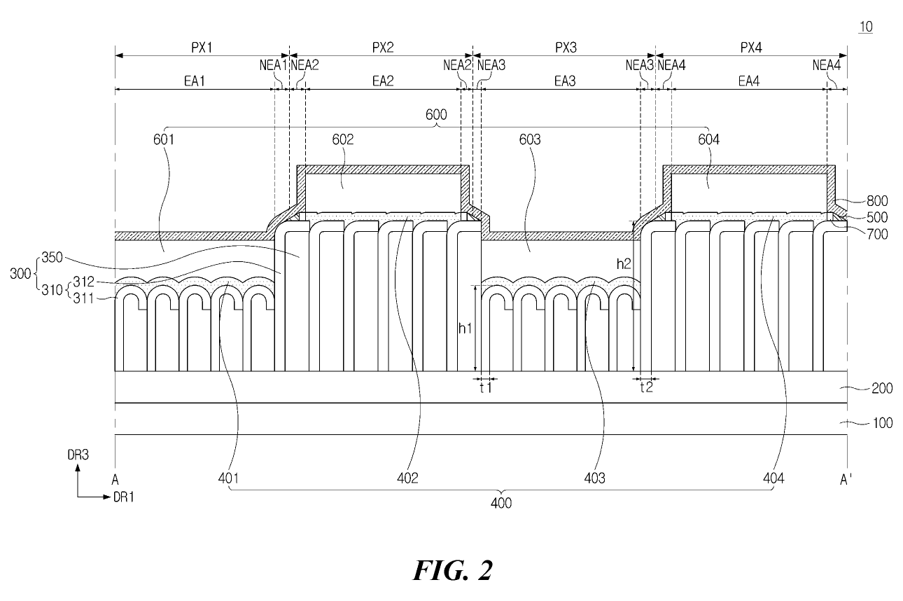

FIG. 2 is a cross-sectional view along line A-A’ in FIG. 1.

Referring to FIG. 2, the display device 10 according to one embodiment may include the substrate 100, the circuit part 200, a step layer 300, the anode electrode 400, the auxiliary layer 500, the light-emitting layer 600, the insulating layer 700, and a cathode electrode 800.

The plurality of sub-pixels PX1, PX2, PX3, and PX4 may be formed on the substrate 100, and the plurality of sub-pixels PX1, PX2, PX3, and PX4 may form one pixel. The plurality of pixels may be formed on the substrate 100. On the substrate 100, the first sub-pixel PX1 may emit red (R) light, the second sub-pixel PX2 may emit blue (B) light, the third sub-pixel PX3 may emit green (G) light, and the fourth sub-pixel PX4 may emit blue (B) light.

The substrate 100 may be a plastic film, a glass substrate, or a semiconductor substrate, such as silicon. The substrate 100 may be made of a transparent material or an opaque material. Since the display device 10 according to one embodiment is configured in a so-called top emission type in which the emitted light is emitted upward (e.g., toward one side in a third direction DR3), both the transparent material and the opaque material may be used as a material for the substrate 100.

The circuit part 200 may be disposed on the substrate 100. The circuit part 200 may include a complementary metal-oxide-semiconductor (CMOS) circuit or at least one thin-film transistor, but various embodiments of the present specification are not limited thereto. The circuit part 200 may include a thin-film transistor, various signal lines, capacitors, etc. The signal lines may include a gate line, a data line, a power line, and a reference line, and the thin-film transistor may include a switching thin-film transistor, a driving thin-film transistor, and a sensing thin-film transistor.

The switching thin-film transistor may be switched according to a gate signal supplied to the gate line to supply a data voltage supplied from the data line to the driving thin-film transistor.

The driving thin-film transistor may be switched according to a data voltage supplied from the switching thin-film transistor to generate data current from power supplied from the power line and supply the data current to the anode electrode 400.

The sensing thin-film transistor may detect a threshold voltage deviation of the driving thin-film transistor, which causes the degradation of image quality, and supply the current of the driving thin-film transistor to the reference line in response to a sensing control signal supplied from the gate line or a separate sensing line.

The capacitor may maintain the data voltage supplied to the driving thin-film transistor for one frame and may be connected to each of a gate terminal and a source terminal of the driving thin-film transistor.

The step layer 300 may be disposed on the circuit part 200. The step layers 300 may be disposed to form steps in the layers on which the anode electrodes 401, 402, 403, and 404 are disposed in the sub-pixels PX1, PX2, PX3, and PX4, respectively, and the step layer 300 may include an organic insulating pattern 310 and a planarization layer 350.

The organic insulating pattern 310 may include a first organic insulating pattern 311 and a second organic insulating pattern 312. The first organic insulating pattern 311 and the second organic insulating pattern 312 may be provided as a plurality of patterns. The plurality of first organic insulating patterns 311 and the plurality of second organic insulating patterns 312 may be disposed to be spaced apart from each other in the first direction DR1.

The first organic insulating pattern 311 may be disposed in the first light-emitting area EA1 of the first sub-pixel PX1 and the third light-emitting area EA3 of the third sub-pixel PX3, and the second organic insulating patterns 312 may be disposed in the second light-emitting area EA2 of the second sub-pixel PX2 and the fourth light-emitting area EA4 of the fourth sub-pixel PX4.

The second organic insulating patterns 312 may also be disposed in the non-light-emitting areas NEA1, NEA2, NEA3, and NEA4 of the sub-pixels PX1, PX2, PX3, and PX4. For example, the second organic insulating pattern 312 may be disposed in the first and second non-light-emitting areas NEA1 and NEA2 between the first sub-pixel PX1 and the second sub-pixel PX2, the second and third non-light-emitting areas NEA2 and NEA3 between the second sub-pixel PX2 and the third sub-pixel PX3, the third and fourth non-light-emitting areas NEA3 and NEA4 between the third sub-pixel PX3 and the fourth sub-pixel PX4, and the fourth non-light-emitting area NEA4 positioned on one side of the fourth sub-pixel PX4 in the first direction DR1.

The first organic insulating pattern 311 and the second organic insulating pattern 312 may extend upward (e.g., toward one sides in the third direction DR3). The one sides of the extended first organic insulating pattern 311 and the extended second organic insulating pattern 312 in the third direction DR3 may be bent.

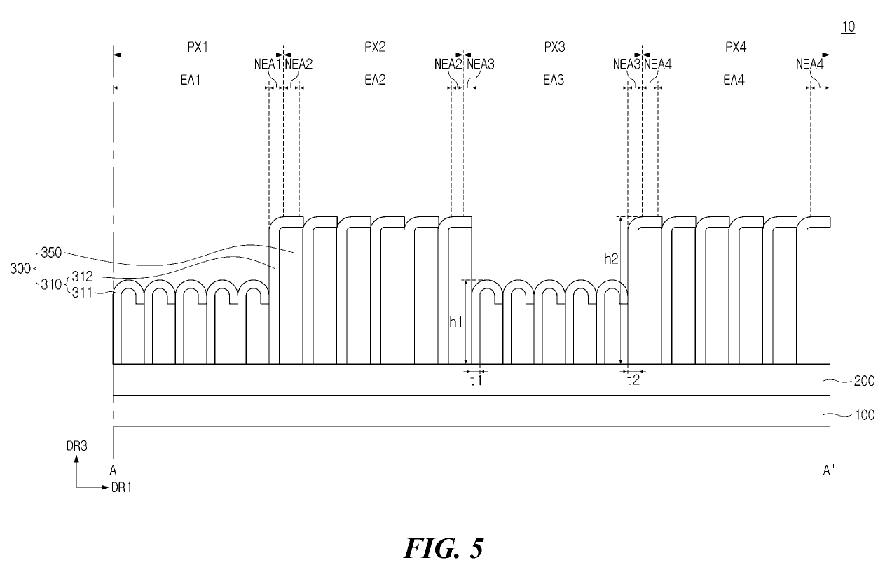

The bent areas of the organic insulating patterns 311 and 312 may be formed through a process of forming and cleaning the organic insulating patterns 311 and 312, which will be described below. Due to the high rotational speed generated during the process of cleaning the organic insulating patterns 311 and 312, the one sides of the organic insulating patterns 311 and 312 in the third direction DR3 may be bent in the same direction. The detailed descriptions thereof will be provided below with reference to FIGS. 5-8.

A width t1 of the first organic insulating pattern 311 and a width t2 of the second organic insulating pattern 312 may be different, and the width t1 of the first organic insulating pattern 311 may be smaller than the width t2 of the second organic insulating pattern 312. In the cleaning process, the smaller the widths of the organic insulating patterns 311 and 312, the more the one sides of the organic insulating patterns 311 and 312 may be bent. Accordingly, when the width t1 of the first organic insulating pattern 311 and the width t2 of the second organic insulating pattern 312 are different, the shapes of the bent areas of the first organic insulating pattern 311 and the second organic insulating pattern 312 may be different.

For example, the first organic insulating pattern 311 may extend upward (e.g., toward the one side in the third direction DR3) and may then be bent to extend downward (e.g., toward the other side in the third direction DR3, and the second organic insulating pattern 312 may extend upward (e.g., toward the one side in the third direction DR3) and may then be bent to extend in a horizontal direction (e.g., toward one side in the first direction DR1).

However, various embodiments of the present specification are not limited thereto, and for example, the first organic insulating pattern 311 may extend upward (e.g., toward the one side in the third direction DR3) and may then be bent to extend in the horizontal direction (e.g., toward one side in the first direction DR1), and the second organic insulating pattern 312 may extend upward (e.g., toward the one side in the third direction DR3) and may then be bent to extend downward (e.g., the other side in the third direction DR3).

In addition, for example, the first organic insulating pattern 311 and the second organic insulating pattern 312 may extend upward (e.g., toward the one sides in the third direction DR3) and may then be bent toward the one sides in the first direction DR1 and toward the one sides in the third direction DR3.

A height of the first organic insulating pattern 311 in the third direction DR3 may be a first surface height h1, and a height of the second organic insulating pattern 312 in the third direction DR3 may be a second surface height h2. As described above, since the width t1 of the first organic insulating pattern 311 is smaller than the width t2 of the second organic insulating pattern 312, the one side of the first organic insulating pattern 311 in the third direction DR3 may be bent more than the one side of the second organic insulating pattern 312 in the third direction DR3. Accordingly, the first surface height h1 of the first organic insulating pattern 311 may be smaller than the second surface height h2 of the second organic insulating pattern 312.

For purposes of description, heights described in the present specification, including the first surface height and the second surface height, may be measured in a direction perpendicular to the substrate, which may correspond to a thickness direction of the display device and a direction in which light is emitted from the light emitting layer. Unless otherwise specified, positional terms such as above, below, upward, downward, and horizontal may be understood with reference to the substrate, and relative height differences between layers may be determined from an upper surface of the substrate. Accordingly, differences between the first surface height and the second surface height refer to differences in positions of upper surfaces of corresponding layers along the direction perpendicular to the substrate.

The bent one sides of the first organic insulating pattern 311 and the second organic insulating pattern 312 may be in direct contact with adjacent other organic insulating patterns 311 and 312. For example, a plurality of first organic insulating patterns 311 disposed in the first light-emitting area EA1 of the first sub-pixel PX1 may be in contact with each other, and thus may function as a single layer having the same height h1. In addition, for example, a plurality of second organic insulating patterns 312 disposed in the second light-emitting area EA2 of the second sub-pixel PX2 may be in contact with each other, and thus may function as a single layer having the same height h2. Likewise, for example, the plurality of first organic insulating patterns 311 disposed in the third light-emitting area EA3 of the third sub-pixel PX3 may be in contact with each other, the plurality of second organic insulating patterns 312 disposed in the fourth light-emitting area EA4 of the fourth sub-pixel PX4 may be in contact with each other, and the plurality of third sub-pixels PX3 and fourth sub-pixels PX4 may function as the single layers having the same heights h1 and h2, respectively.

Accordingly, a layer having a step may be formed in each of the sub-pixels PX1, PX2, PX3, and PX4 by the organic insulating patterns 311 and 312. In this case, the height h1 of the layer formed by the first organic insulating pattern 311 may be smaller than the height h2 of the layer formed by the second organic insulating pattern 312. By forming the layer having the step in each of the sub-pixels PX1, PX2, PX3, and PX4, the sizes of the sub-pixels PX1, PX2, PX3, and PX4 can be easily changed. In addition, areas of the second and fourth sub-pixels PX2 and PX4 that emit light may be increased, thereby improving the color balance of the display device 10 and extending the lifetime of the display device 10.

The planarization layer 350 may be disposed between adjacent organic insulating patterns 311 and 312. The upper portions (e.g., the one sides in the third direction DR3) of the organic insulating patterns 311 and 312 may be bent, and the bent upper portions may be in direct contact with other organic insulating patterns 311 and 312, respectively. Accordingly, empty spaces may be formed between the adjacent organic insulating patterns 311 and 312 and the circuit part 200. For example, the empty spaces may have a shape that reflects the shapes of the adjacent organic insulating pattern 311 and 312. The planarization layer 350 may be disposed to fill the empty spaces.

The planarization layer 350 may be made of an inorganic insulation material or formed in a structure in which an inorganic insulation material and an organic insulation material are alternately stacked, but various embodiments of the present specification are not necessarily limited thereto. For example, any material with high surface tension or viscosity may be used to form the planarization layer 350.

The anode electrode 400 may be disposed on the organic insulating patterns 311 and 312. The anode electrode 400 may include the first anode electrode 401, the second anode electrode 402, the third anode electrode 403, and the fourth anode electrode 404.

The first anode electrode 401 may be disposed in the first light-emitting area EA1 of the first sub-pixel PX1, the second anode electrode 402 may be disposed in the second light-emitting area EA2 of the second sub-pixel PX2, the third anode electrode 403 may be disposed in the third light-emitting area EA3 of the third sub-pixel PX3, and the fourth anode electrode 404 may be disposed in the fourth light-emitting area EA4 of the fourth sub-pixel PX4.

The first to fourth anode electrodes 401, 402, 403, and 404 may be in direct contact with the organic insulating patterns 311 and 312. As described above, since the upper portions (e.g., the one sides in the third direction DR3) of the organic insulating patterns 311 and 312 may be bent, the anode electrodes 401, 402, 403, and 404 may have the steps caused by the bent areas of the organic insulating patterns 311 and 312.

The first anode electrode 401 and the third anode electrode 403 may be disposed on the first organic insulating pattern 311, and the second anode electrode 402 and the fourth anode electrode 404 may be disposed on the second organic insulating pattern 312. Accordingly, the first anode electrode 401 and the third anode electrode 403 may be positioned below (e.g., on the other sides in the third direction DR3) the second anode electrode 402 and the fourth anode electrode 404.

The anode electrode 400 may include a material with high light transmittance. For example, the anode electrode 400 may include ITO, IZO, or TiN, but various embodiments of the present specification are not limited thereto. The anode electrode 400 may function as an anode of the display device 10.

The insulating layers 700 may be disposed on one sides and the other sides of the second anode electrode 402 and the fourth anode electrode 404 in the first direction DR1. The insulating layers 700 may be disposed at the boundaries between the sub-pixels PX1, PX2, PX3, and PX4 and disposed in the non-light-emitting areas NEA1, NEA2, NEA3, and NEA4 of the sub-pixels PX1, PX2, PX3, and PX4. For example, the insulating layers 700 are illustrated as being disposed only in the second non-light-emitting area NEA2 and the fourth non-light-emitting area NEA4, but may be disposed across the first non-light-emitting area NEA1 and the second non-light-emitting area NEA2, across the second non-light-emitting area NEA2 and the third non-light-emitting area NEA3, or across the third non-light-emitting area NEA3 and the fourth non-light-emitting area NEA4.

The insulating layer 700 may be made of an inorganic insulation material, but is not necessarily limited thereto. For example, the insulating layer 700 may be made of an inorganic material, such as silicon nitride (SiNₓ), silicon oxide (SiOₓ), aluminum oxide (Al₂O₃), etc., but various embodiments of the present specification are not limited thereto.

The insulating layers 700 may insulate the second to fourth anode electrodes 402, 403, and 404 and the cathode electrode 800, which will be described below.

The auxiliary layers 500 may be disposed on one sides and the other sides of the second anode electrode 402 and the fourth anode electrode 404 in the first direction DR1. The auxiliary layers 500 may be disposed at the boundaries between the sub-pixels PX1, PX2, PX3, and PX4 and disposed in the non-light-emitting areas NEA1, NEA2, NEA3, and NEA4 of the sub-pixels PX1, PX2, PX3, and PX4.

Near the boundary between the first sub-pixel PX1 and the second sub-pixel PX2, the insulating layer 700 may be disposed between the auxiliary layer 500 and the second anode electrode 402. Near the boundary between the second sub-pixel PX2 and the third sub-pixel PX3, the insulating layer 700 may be disposed between the auxiliary layer 500 and the second anode electrode 402. Near the boundary between the third sub-pixel PX3 and the fourth sub-pixel PX4, the insulating layer 700 may be disposed between the auxiliary layer 500 and the fourth anode electrode 404. On one side of the fourth anode electrode 404 in the first direction DR1, the insulating layer 700 may be disposed between the fourth anode electrode 404 and the auxiliary layer 500.

The auxiliary layer 500 may be made of the same material as the cathode electrode 800, which will be described below. For example, the auxiliary layer 500 may be formed of a translucent electrode and may include silver (Ag) or magnesium (Mg), but various embodiments of the present specification are not limited thereto.

The auxiliary layer 500 may also include a material with high light transmittance. For example, the auxiliary layer 500 may include ITO, IZO, or TiN, but various embodiments of the present specification are not limited thereto.

The auxiliary layer 500 may be in direct contact with side surfaces of the second organic insulating pattern 312 and the insulating layer 700. The auxiliary layers 500 can prevent the cathode electrodes 800 from being disconnected due to the steps between the sub-pixels PX1, PX2, PX3, and PX4. Accordingly, the auxiliary layer 500 may have a triangular shape whose width narrows upward (e.g., toward one side in the third direction DR3), but various embodiments of the present specification are not limited thereto.

The light-emitting layer 600 may be disposed on the anode electrodes 401, 402, 403, and 404. The light-emitting layer 600 may include a first light-emitting layer 601 disposed on the first anode electrode 401, a second light-emitting layer 602 disposed on the second anode electrode 402, a third light-emitting layer 603 disposed on the third anode electrode 403, and a fourth light-emitting layer 604 disposed on the fourth anode electrode 404. The light-emitting layers 601, 602, 603, and 604 may be physically separated. The light-emitting layers 601, 602, 603, and 604 may be in direct contact with upper surfaces of the anode electrodes 401, 402, 403, and 404, respectively.

The first light-emitting layer 601 and the third light-emitting layer 603 may be disposed on the first organic insulating patterns 311, and the second light-emitting layer 602 and the fourth light-emitting layer 604 may be disposed on the second organic insulating pattern 312. Accordingly, the first light-emitting layer 601 and the third light-emitting layer 603 may be positioned below (e.g., on the other side in the third direction DR3) the second light-emitting layer 602 and the fourth light-emitting layer 604.

One side surface of the first light-emitting layer 601 in the first direction DR1 and one side surface of the third light-emitting layer 603 in the first direction DR1 may be in direct contact with the second organic insulating patterns 312, and the other side surface of the third light-emitting layer 603 in the first direction DR1 may be in direct contact with the planarization layer 350.

The first light-emitting layer 601 may emit red (R) light, the second light-emitting layer 602 and the fourth light-emitting layer 604 may emit blue (B) light, and the third light-emitting layer 603 may emit green (G) light. However, various embodiments of the present specification are not limited thereto, and for example, the light-emitting layer 600 may emit white (W) light.

The cathode electrode 800 may be disposed on the light-emitting layer 600. The cathode electrode 800 may function as a cathode of the display device 10. The cathode electrodes 800 may be disposed on the sub-pixels PX1, PX2, PX3, and PX4 and between the sub-pixels PX1, PX2, PX3, and PX4. That is, the cathode electrode 800 may be formed to function as a common layer across the first to fourth sub-pixels PX1, PX2, PX3, and PX4.

The cathode electrodes 800 may be in direct contact with the upper surfaces of the light-emitting layers 601, 602, 603, and 604 and may be in direct contact with the auxiliary layers 500 in the non-light-emitting areas NEA1, NEA2, NEA3, and NEA4. The cathode electrode 800 may also be in direct contact with an upper surface of the insulating layer 700 and may also be in direct contact with side surfaces of the second and fourth light-emitting layers 602 and 604.

The cathode electrode 800 may also be in direct contact with the second organic insulating pattern 312. When the bent area of the second organic insulating pattern 312 is in direct contact with the cathode electrode 800, the cathode electrode 800 can be prevented from being disconnected by the bent area.

The cathode electrode 800 may be formed of a translucent electrode and may include silver (Ag) or magnesium (Mg), but various embodiments of the present specification are not limited thereto.

FIG. 3 is a cross-sectional view along line B-B’ in FIG. 1.

Referring to FIG. 3, FIG. 3 is a cross-sectional view illustrating an electrical connection relationship in the non-light-emitting area NEA of the display device 10 according to one embodiment, and FIG. 3 may be a cross-sectional view of the pad contact portions.

The circuit part 200 may include the first circuit part 251 disposed in the first sub-pixel PX1, the second circuit part 252 disposed in the second sub-pixel PX2, the third circuit part 253 disposed in the third sub-pixel PX3, and the fourth circuit part 254 disposed in the fourth sub-pixel PX4.

The first circuit part 251 may be electrically connected to the first anode electrode 401 through the contact hole CT, the second circuit part 252 may be electrically connected to the second anode electrode 402 through the contact hole CT, the third circuit part 253 may be electrically connected to the third anode electrode 403 through the contact hole CT, and the fourth circuit part 254 may be electrically connected to the fourth anode electrode 404 through the contact hole CT.

Although not illustrated, the second organic insulating patterns 312 may be disposed below the first anode electrode and the third anode electrode 401 and 403. Accordingly, steps may not be formed between the first to fourth anode electrodes 401, 402, 403, and 404.

When no steps are formed between the first to fourth anode electrodes 401, 402, 403, and 404, organic insulating patterns having a surface height (e.g., a height in the third direction DR3) greater than that of the second organic insulating pattern may be additionally disposed between the anode electrodes 401, 402, 403, and 404. Accordingly, the anode electrodes 401, 402, 403, and 404 may be insulated.

The drawing illustrates the light-emitting layers 601, 602, 603, and 604, but in some embodiments, the light-emitting layers 601, 602, 603, and 604 may not be disposed. As described above, since no steps are formed between the first to fourth anode electrodes 401, 402, 403, and 404, the stability of the process of forming the contact holes CT connected to the first to fourth anode electrodes 401, 402, 403, and 404 can be enhanced, and the efficiency of the process of removing the light-emitting layers 601, 602, 603, and 604 can be improved.

Since the remaining parts have been described above in FIG. 2, the detailed descriptions thereof will be omitted below.

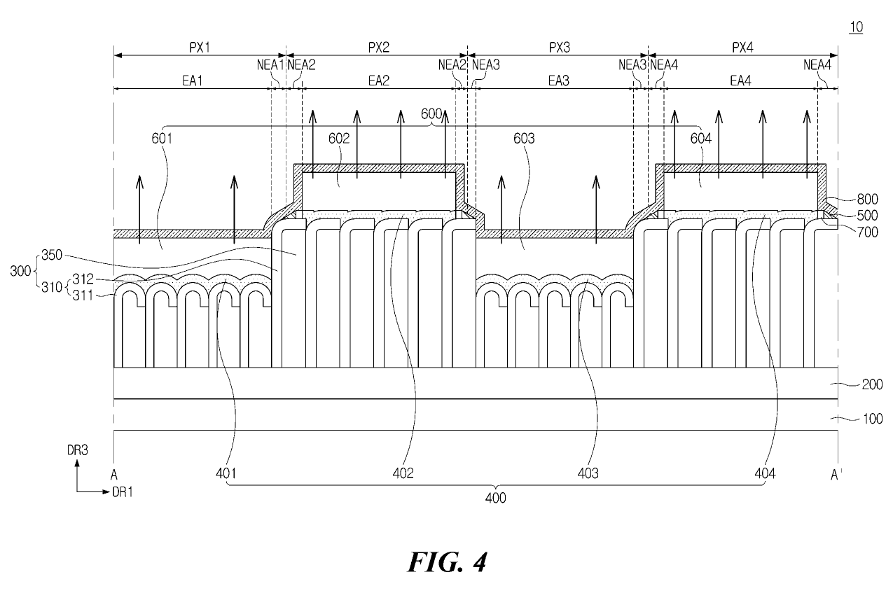

FIG. 4 is a schematic view illustrating an optical path in FIG. 2.

Referring to FIG. 4, light emitted from the light-emitting layer 600 may be emitted upward (e.g., toward one side in the third direction DR3). Here, the term “upward” refers to a direction in which a user can perceive light, and for example, although not illustrated, may refer to a direction toward an encapsulation layer disposed on the cathode electrode 800.

Due to the steps formed by the organic insulating patterns 310, the second and fourth light-emitting layers 602 and 604 may be disposed above (e.g., toward the one side in the third direction DR3) the first and third light-emitting layers 601 and 603. Accordingly, a user can perceive more light emitted from the second and fourth light-emitting layers 602 and 604 than light emitted from the first and third light-emitting layers 601 and 603.

Since the remaining parts have been described above in FIG. 2, the detailed descriptions thereof will be omitted below.

Hereinafter, a method of manufacturing the display device 10 according to one embodiment will be described. In the descriptions of FIGS. 5-18, the detailed descriptions of the components already described with reference to FIGS. 1-4 will be omitted.

FIGS. 5-18 are cross-sectional views for each process in a method of manufacturing the display device in FIG. 1.

Referring to FIG. 5, the circuit part 200 may be formed on the substrate 100, and a plurality of first organic insulating patterns 311 and a plurality of second organic insulating patterns 312 may be formed on the circuit part 200.

The plurality of first organic insulating patterns 311 may be formed in the first light-emitting area EA and the third light-emitting area EA3, and the plurality of second organic insulating patterns 312 may be formed in the second light-emitting area EA2 and the fourth light-emitting area EA4. The second organic insulating patterns 312 may also be formed in the non-light-emitting areas NEA1, NEA2, NEA3, and NEA4. Upper portions (e.g., one sides in the third direction DR3) of the plurality of first organic insulating patterns 311 and upper portions of the plurality of second organic insulating patterns 312 may be bent.

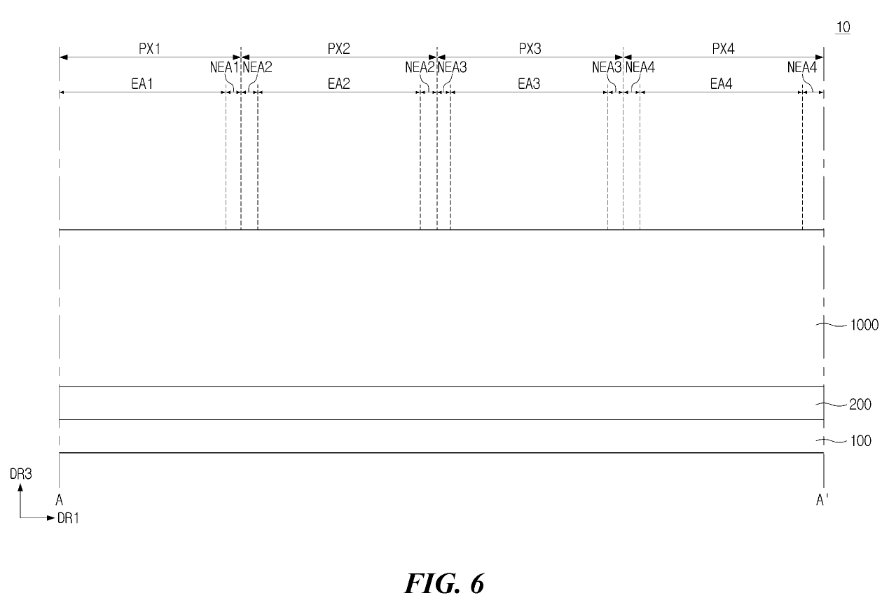

The width t1 of the first organic insulating pattern 311 may be smaller than the width of the second organic insulating pattern 312, the first surface height h1 of the first organic insulating pattern 311 may be smaller than the second surface height h2 of the second organic insulating pattern 312, and the first organic insulating pattern 311 may be bent more than the second organic insulating pattern 312. As described above, a method of forming organic insulating patterns having different widths and surface heights will be described with reference to FIGS. 6-8.

Referring to FIG. 6, an organic layer 1000 may be formed on the circuit part 200, and the organic layer 1000 may be formed as a single layer extending in the first direction DR1.

The organic layer 1000 may include an organic material, for example, a negative-type photosensitive material, but various embodiments of the present specification are not limited thereto. The organic layer 1000 may include, for example, propylene glycol methyl ether acetate (PGMEA), but various embodiments of the present specification are not limited thereto.

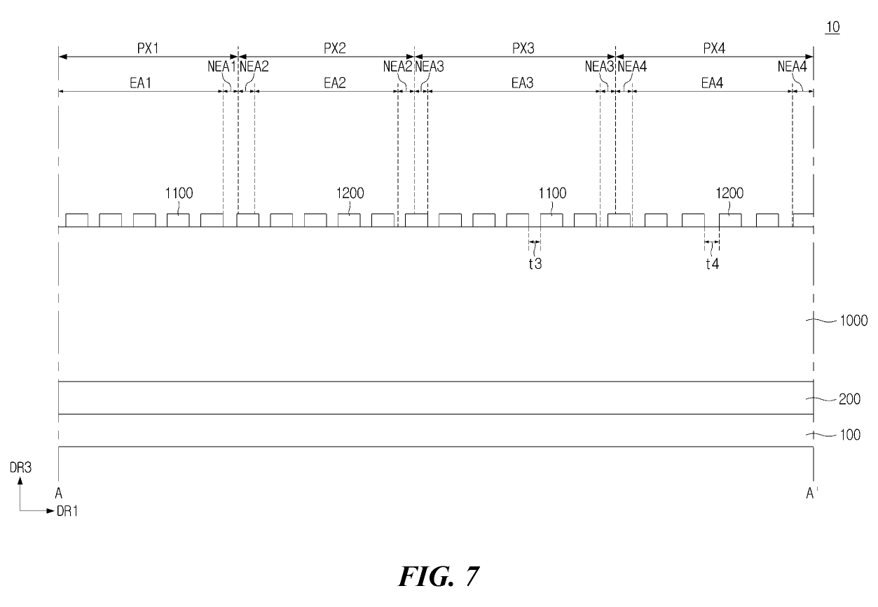

Referring to FIG. 7, first fine mask layers 1100 and second fine mask layers 1200 may be formed on the organic layer 1000. The first fine mask layer 1100 and the second fine mask layer 1200 may be provided as a plurality of layers.

The first fine mask layers 1100 may be formed in the first light-emitting area EA1 and the third light-emitting area EA3, and the second fine mask layers 1200 may be formed in the second light-emitting area EA2, the fourth light-emitting area EA4, and the non-light-emitting areas NEA1, NEA2, NEA3, and NEA4.

A distance t3 between adjacent first fine mask layers 1100 may be equal to the width t1 (see FIG. 5) of the first organic insulating pattern 311 (see FIG. 5) described above with reference to FIG. 5, and a distance t4 between adjacent second fine mask layers 1200 may be equal to the width t2 (see FIG. 5) of the second organic insulating pattern 312 (see FIG. 5) described above with reference to FIG. 5. Accordingly, the distance t3 between adjacent first fine mask layers 1100 may be smaller than the distance t4 between adjacent second fine mask layers 1200.

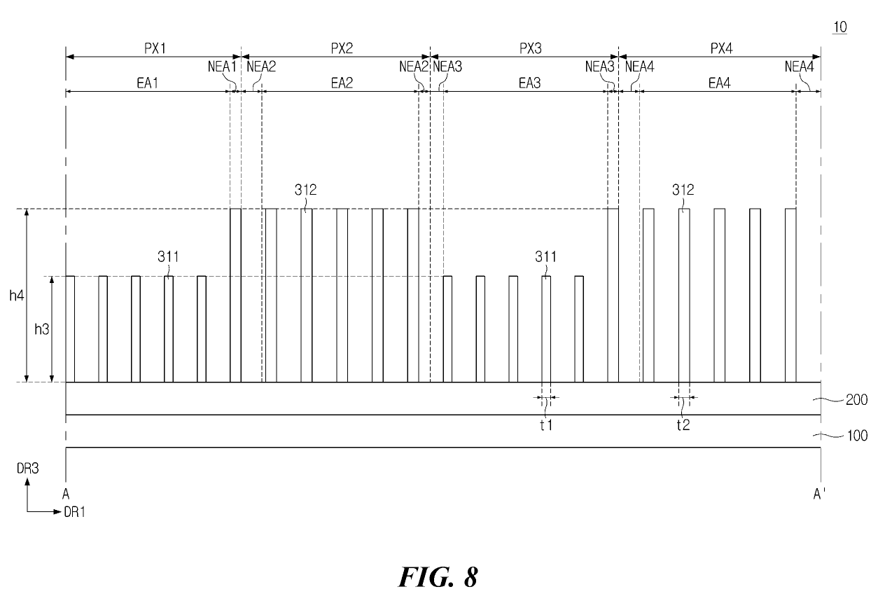

In a stepper process, the shorter the distance between adjacent mask layers, the lower the height of the final pattern formed on the organic layer 1000 by diffracted light. That is, a height h3 (see FIG. 8) of the first organic insulating pattern 311 (see FIG. 8) formed by the first fine mask layer 1100 may be smaller than a height h4 (see FIG. 8) of the second organic insulating pattern formed by the second fine mask layer 1200.

Referring to FIG. 8, FIG. 8 illustrates a state of the organic layer 1000 after a puddle process is performed.

In FIG. 7, as described above, the height h3 of the first organic insulating pattern 311 may be smaller than the height h4 of the second organic insulating pattern 312.

In a rinse process, when aspect ratios of the organic insulating patterns 311 and 312 are high, the upper portions of the organic insulating patterns 311 and 312 may be bent due to negative pressure generated by a high rotational speed and a high surface tension of a rinse liquid. The high aspect ratio may, for example, be when the heights and widths of the organic insulating patterns 311 and 312 are 2 μm or more and less than 0.8 μm, respectively. However, various embodiments of the present specification are not limited thereto.

As the widths of the organic insulating patterns 311 and 312 decrease, the degree of bending may increase. Accordingly, the degree of bending of the upper portion of the first organic insulating pattern 311 may be greater than the degree of bending of the upper portion of the second organic insulating pattern 312. However, various embodiments of the present specification are not limited thereto, and for example, by adjusting the rotational speed during the rinse process, the degrees of bending of the upper portions of the organic insulating patterns 311 and 312 may be the same or similar.

Accordingly, the organic insulating patterns 311 and 312 having steps may be formed with just a single stepper process.

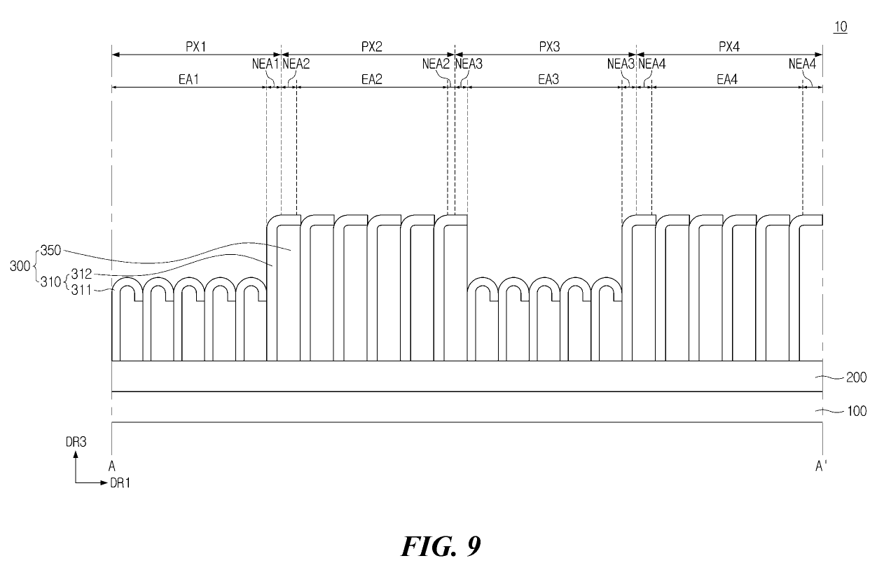

Referring to FIG. 9, the planarization layer 350 may be formed between adjacent organic insulating patterns 311 and 312. The planarization layers 350 may be formed by filling the space between the organic insulating patterns 311 and 312 and lower portions of the bent areas of the organic insulating patterns 311 and 312. The planarization layer 350 may be formed using an inkjet method and may also be formed by repeating the inkjet process two or more times.

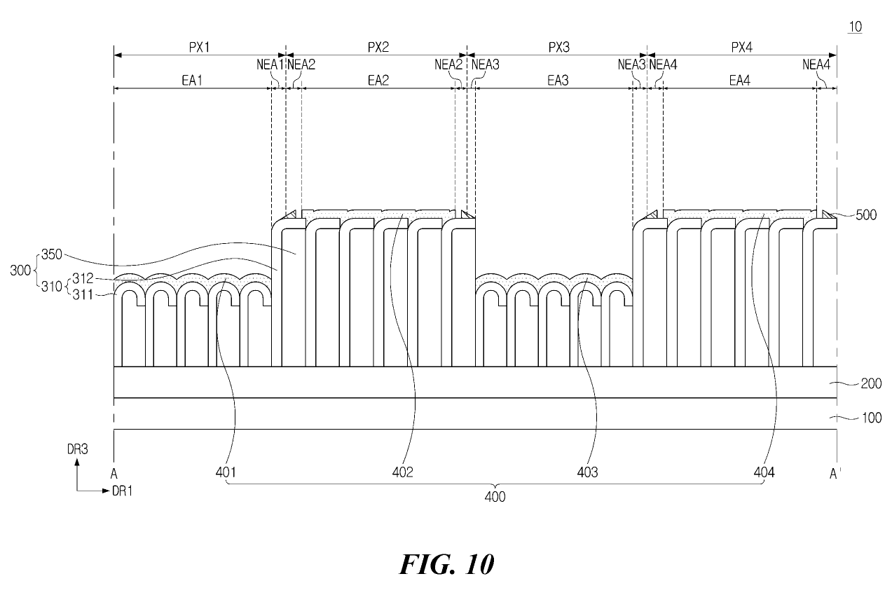

Referring to FIG. 10, the anode electrodes 401, 402, 403, and 404 may be formed on the organic insulating patterns 311 and 312 in the light-emitting areas EA1, EA2, EA3, and EA4, respectively, and the auxiliary layers 500 may be formed on both sides of the second anode electrode 402 and the fourth anode electrode 404 in the first direction DR1.

The second anode electrode 402 and the auxiliary layers 500 formed on both sides thereof may be formed to be spaced apart from each other in the first direction DR1, and the fourth anode electrode 404 and the auxiliary layers 500 formed on both sides thereof may be formed to be spaced apart from each other in the first direction DR1.

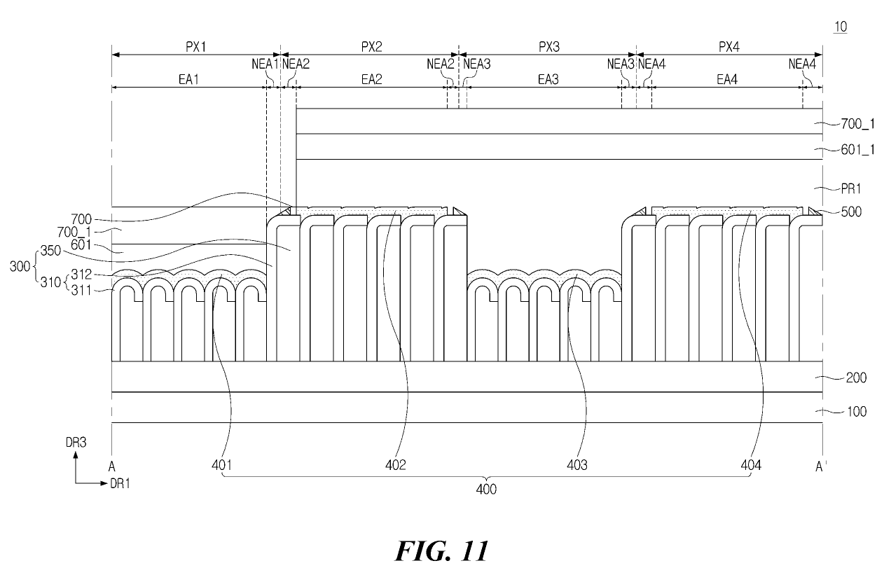

Referring to FIG. 11, a first photosensitive film PR1 may be formed on the anode electrodes 402, 403, and 404, the organic insulating patterns 311 and 312, and the auxiliary layers 500, which are formed in the second light-emitting area EA2, the second non-light-emitting area NEA2 positioned at one side of the second light-emitting area EA2 in the first direction DR1, and the third to fourth sub-pixels PX3 and PX4.

The first photosensitive film PR1 may include an organic material, for example, a negative-type photosensitive material, but various embodiments of the present specification are not limited thereto.

The first light-emitting layer 601 may be formed on the first anode electrode 401, and a 1-1 light-emitting layer 601_1 may be formed on the first photosensitive film PR1. The 1-1 light-emitting layer 601_1 may be made of the same material as the first light-emitting layer 601, and may be, for example, a material that emits red (R) light.

The insulating layer 700 may be formed on the second organic insulating pattern 312 disposed in the second non-light-emitting area NEA2 positioned at the other side of the second light-emitting area EA2 in the first direction DR1, and the insulating layer 700 may be formed between the auxiliary layer 500 and the second anode electrode 402. First sacrificial insulating layers 700_1 may be formed on the first light-emitting layer 601, the auxiliary layer 500 formed between the first sub-pixel PX1 and the second sub-pixel PX2, and the 1-1 light-emitting layer 601_1. The first sacrificial insulating layer 700_1 may be made of the same material as the insulating layer 700.

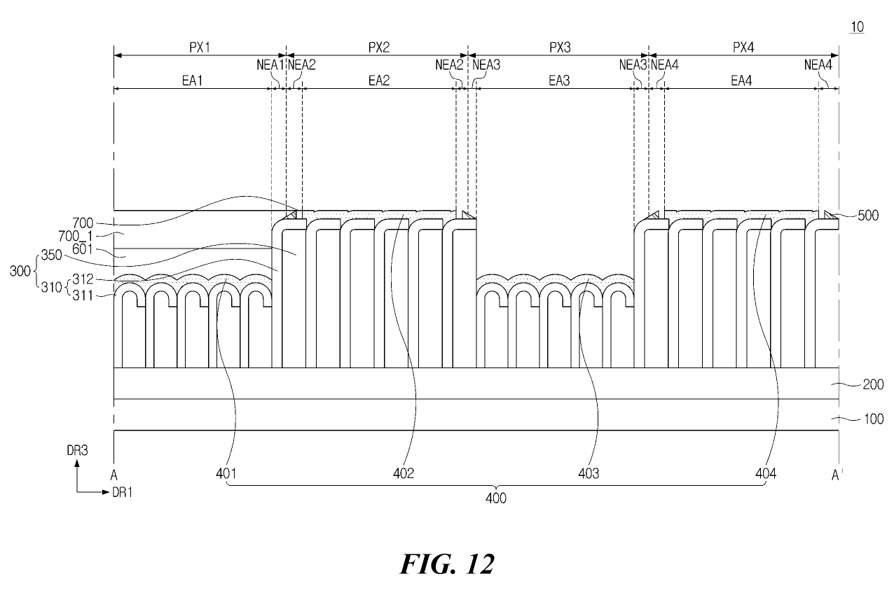

Referring to FIG. 12, FIG. 12 illustrates a state after the first photosensitive film PR1 (see FIG. 11), the 1-1 light-emitting layer 601_1 (see FIG. 11), and the first sacrificial insulating layer 700_1 (see FIG. 11) are removed.

The first photosensitive film PR1 (see FIG. 11) may be removed. When the first photosensitive film PR1 (see FIG. 11) is removed, both the 1-1 light-emitting layer 601_1 (see FIG. 11) formed on the first photosensitive film PR1 (see FIG. 11) and the first sacrificial insulating layer 700_1 (see FIG. 11) formed on the first photosensitive film PR1 (see FIG. 11) may be removed.

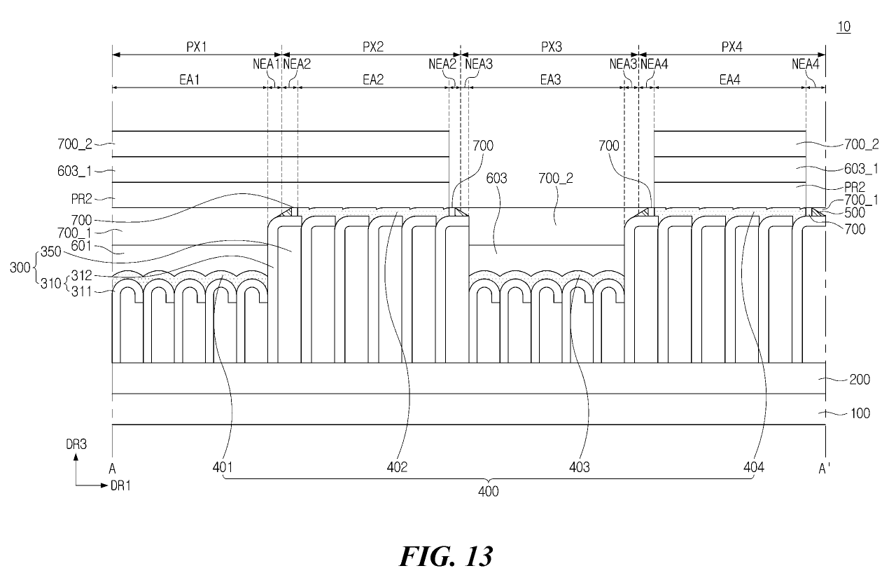

Referring to FIG. 13, a second photosensitive film PR2 may be formed on the first sacrificial insulating layers 700_1, the insulating layers 700, and the second anode electrode 402 of the first and second sub-pixels PX1 and PX2. In this case, the second photosensitive film PR2 may not be formed on the insulating layer 700 and the auxiliary layer 500, which are formed on the one side of the second anode electrode 402 in the first direction DR1. The second photosensitive film PR2 may also be formed on the fourth anode electrode 404.

The second photosensitive film PR2 may include the same material as the first photosensitive film PR1 (see FIG. 11), and for example, the second photosensitive film PR2 may include a negative-type photosensitive material, but various embodiments of the present specification are not limited thereto.

The third light-emitting layer 603 may be formed on the first anode electrode 403, and a 3-1 light-emitting layer 603_1 may be formed on the second photosensitive film PR2. The 3-1 light-emitting layer 603_1 may be made of the same material as the third light-emitting layer 603, and may be, for example, a material that emits green (G) light.

The insulating layer 700 may be formed on the second organic insulating pattern 312 disposed in the second non-light-emitting area NEA2 positioned at the one side of the second light-emitting area EA2 in the first direction DR1, and the insulating layer 700 may be formed between the auxiliary layer 500 and the second anode electrode 402. The insulating layer 700 may be formed on the second organic insulating pattern 312 disposed in the fourth non-light-emitting area NEA4, and the insulating layer 700 may be formed between the auxiliary layer 500 and the second anode electrode 402.

A second sacrificial insulating layer 700_2 may be formed on the 3-1 light-emitting layer 603_1, the auxiliary layer 500 formed between the second sub-pixel PX2 and the third sub-pixel PX3, the third light-emitting layer 603, the auxiliary layer 500 formed between the third sub-pixel PX3 and the fourth sub-pixel PX4, and the auxiliary layer 500 formed on one side of the fourth electrode 404 in the first direction DR1. The second sacrificial insulating layer 700_2 may be the same material as the insulating layer 700 and the first sacrificial insulating layer 700_1.

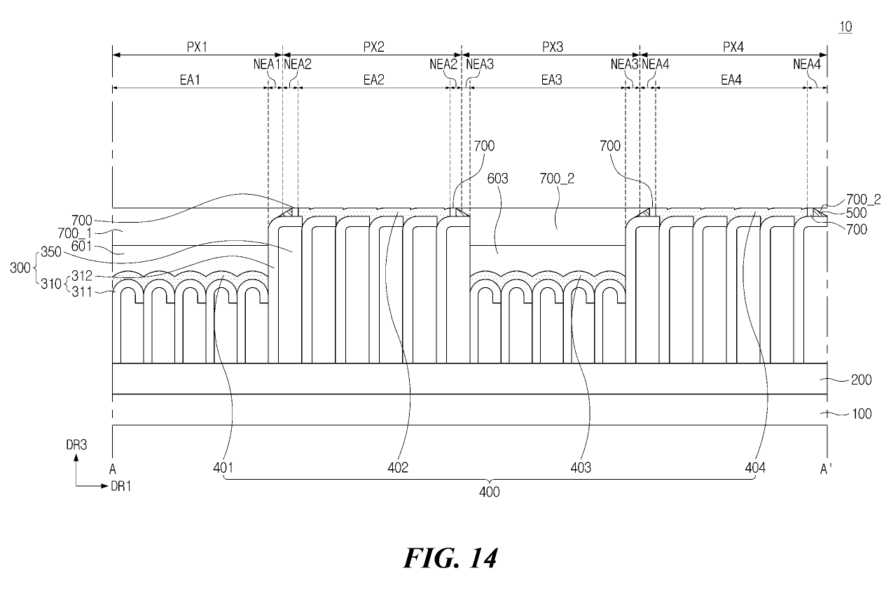

Referring to FIG. 14, FIG. 14 illustrates a state after the second photosensitive film PR2 (see FIG. 13), the 3-1 light-emitting layer 603_1 (see FIG. 13), and the second sacrificial insulating layer 700_2 (see FIG. 13) are removed.

The second photosensitive film PR2 (see FIG. 13) may be removed. When the second photosensitive film PR2 (see FIG. 13) is removed, both the 3-1 light-emitting layer 603_1 (see FIG. 13) formed on the second photosensitive film PR2 (see FIG. 13) and the second sacrificial insulating layer 700_2 (see FIG. 13) formed on the second photosensitive film PR2 (see FIG. 13) may be removed.

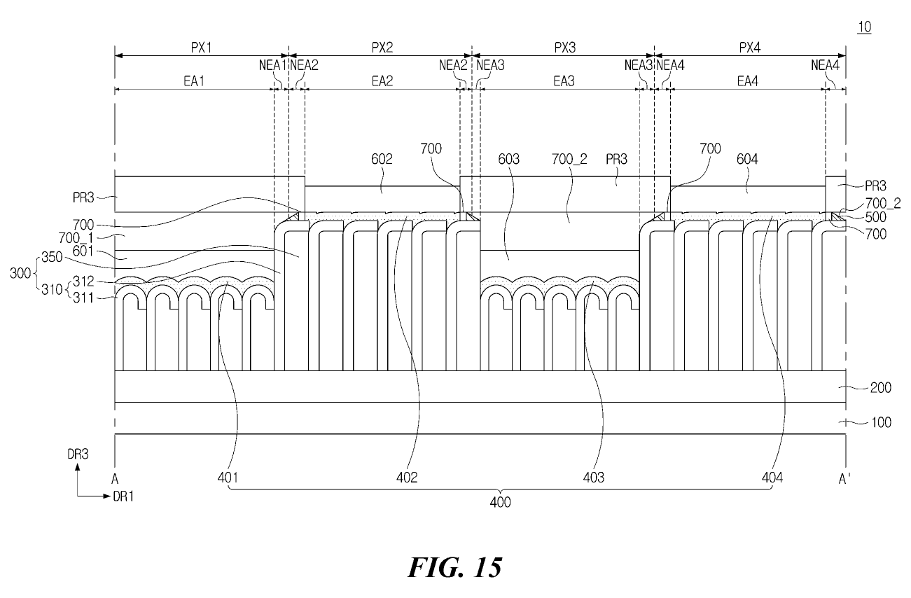

Referring to FIG. 15, a third photosensitive film PR3 may be formed in areas other than the second light-emitting area EA2 and the fourth light-emitting area EA4.

The third photosensitive film PR3 may include the same material as the first photosensitive film PR1 (see FIG. 11), and for example, the third photosensitive film PR3 may include a negative-type photosensitive material, but various embodiments of the present specification are not limited thereto.

The second light-emitting layer 602 may be formed on the second anode electrode 402, and the fourth light-emitting layer 604 may be formed on the fourth anode electrode 404. The second light-emitting layer 602 and the fourth light-emitting layer 604 may be made of the same material, for example, a material that emits blue (B) light.

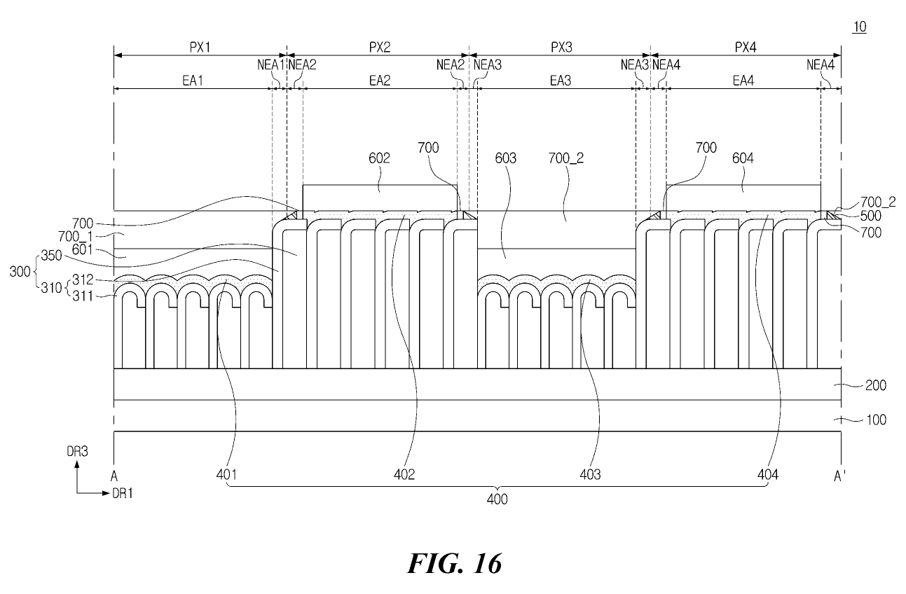

Referring to FIG. 16, the third photosensitive film PR3 (see FIG. 15) may be removed, and FIG. 16 illustrates a state after the third photosensitive film PR3 (see FIG. 15) is removed.

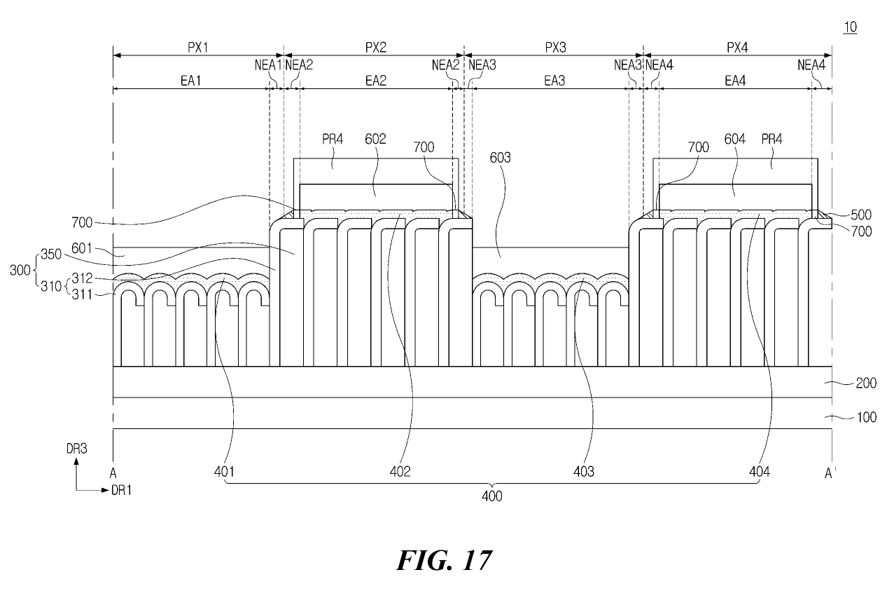

Referring to FIG. 17, FIG. 17 illustrate a state after the sacrificial insulating layers 700_1 and 700_2 are removed.

A fourth photosensitive film PR4 may be formed on the second light-emitting layer 602 and the insulating layer 700 formed in the second sub-pixel PX2 and may also be formed on the fourth light-emitting layer 604 and the insulating layer 700 formed in the fourth sub-pixel PX4. The fourth photosensitive film PR4 may be formed to surround upper and side surfaces of the second light-emitting layer 602 and upper and side surfaces of the fourth light-emitting layer 604.

The fourth photosensitive film PR4 may include the same material as the first photosensitive film PR1 (see FIG. 11), and for example, the fourth photosensitive film PR4 may include a negative-type photosensitive material, but various embodiments of the present specification are not limited thereto.

The first sacrificial insulating layers 700_1 (see FIG. 16) formed in the first sub-pixel PX1 and the second sub-pixel PX2 may be removed, and the second sacrificial insulating layers 700_2 (see FIG. 16) formed in the second to fourth sub-pixels PX2, PX3, and PX4 may be removed.

The first and second sacrificial insulating layers 700_1 and 700_2 (see FIG. 16) may be removed by etching. By forming the fourth photosensitive film PR4, the insulating layers 700 formed in the second sub-pixel PX2 and the fourth sub-pixel PX4 may not be etched during the etching process.

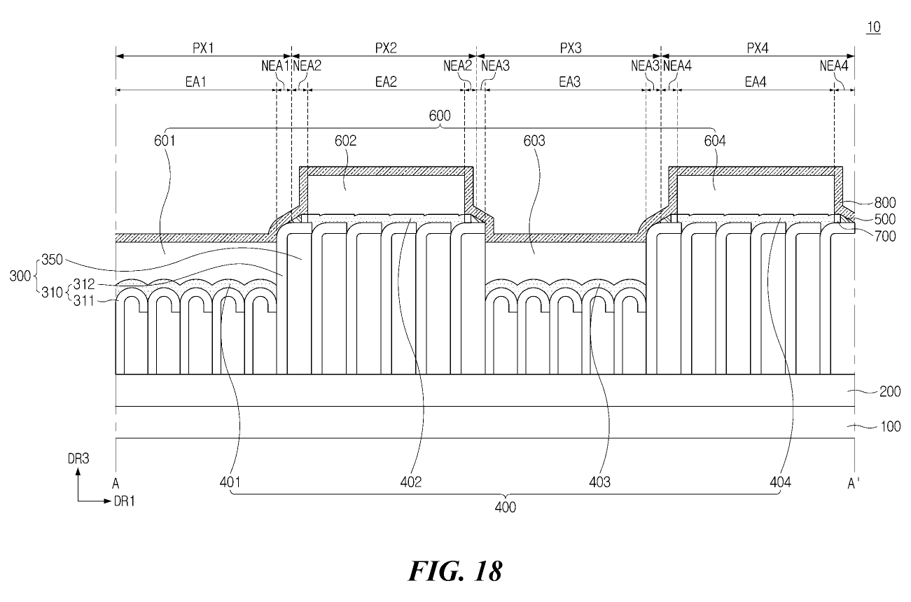

Referring to FIG. 18, the cathode electrode 800 may be formed to function as a common layer across the first to fourth sub-pixels PX1, PX2, PX3, and PX4.

The cathode electrode 800 may be formed to be in direct contact with the light-emitting layers 601, 602, 603, and 604, the insulating layer 700, and the auxiliary layer 500 and formed to be in direct contact with the side surfaces of the second and fourth light-emitting layers 602 and 604.

Since the remaining parts have been described above in FIG. 2, the detailed descriptions thereof will be omitted below.

A display device according to various embodiments of the present specification may be described as follows.

According to various embodiments of the present specification, there is provided a display device including a substrate on which a first sub-pixel and a second sub-pixel are defined, a plurality of first organic insulating patterns disposed on the substrate of the first sub-pixel and having a first surface height, a plurality of second organic insulating patterns disposed on the substrate of the second sub-pixel and having a second surface height, a first anode electrode on the plurality of first organic insulating patterns, and a second anode electrode on the plurality of second organic insulating patterns, in which the second surface height is greater than the first surface height.

The display device according to various embodiments of the present specification may further include a planarization layer which fills spaces between adjacent first organic insulating patterns and spaces between adjacent second organic insulating patterns, in which the plurality of first organic insulating patterns may be disposed to be spaced apart from each other in a first direction, and the plurality of second organic insulating patterns may be disposed to be spaced apart from each other in the first direction.

In the display device according to various embodiments of the present specification, the first organic insulating patterns and the second organic insulating patterns may extend upward and may then be bent.

In the display device according to various embodiments of the present specification, the first organic insulating pattern may extend upward and may then be bent to extend downward, and the second organic insulating pattern may extend upward and may then bent in a horizontal direction.

In the display device according to various embodiments of the present specification, widths of the plurality of first organic insulating patterns may be smaller than widths of the plurality of second organic insulating patterns.

In the display device according to various embodiments of the present specification, the first anode electrode may be in direct contact with the plurality of first organic insulating patterns, and the second anode electrode may be in direct contact with the plurality of second organic insulating patterns.

In the display device according to various embodiments of the present specification, the first anode electrode may be positioned below the second anode electrode.

The display device according to various embodiments of the present specification may further include a first light-emitting layer on the first anode electrode of the first sub-pixel, and a second light-emitting layer on the second anode electrode of the second sub-pixel, in which the first light-emitting layer and the second light-emitting layer may be separated.

In the display device according to various embodiments of the present specification, side surfaces of the first light-emitting layer may be in direct contact with the second organic insulating pattern.

The display device according to various embodiments of the present specification may further include a cathode electrode on the first light-emitting layer and the second light-emitting layer.

In the display device according to various embodiments of the present specification, the cathode electrode may be in direct contact with side surfaces of the second light-emitting layer.

The display device according to various embodiments of the present specification may further include an auxiliary layer on the second organic insulating pattern.

In the display device according to various embodiments of the present specification, the auxiliary layer may be in direct contact with the second organic insulating pattern.

In the display device according to various embodiments of the present specification, the auxiliary layer may be disposed on each of one side and the other side of the second anode electrode in the first direction.

The display device according to various embodiments of the present specification may further include an insulating layer disposed between the auxiliary layer and the second anode electrode.

In the display device according to various embodiments of the present specification, the cathode electrode may be in direct contact with the insulating layer.

In the display device according to various embodiments of the present specification, the first sub-pixel may include a first light-emitting area and a first non-light-emitting area around the first light-emitting area, the second sub-pixel may include a second light-emitting area and a second non-light-emitting area around the second light-emitting area, and the auxiliary layer and the insulating layer may be disposed across the first non-light-emitting area and the second non-light-emitting area.

In the display device according to various embodiments of the present specification, the cathode electrode may be in direct contact with the auxiliary layer.

In the display device according to various embodiments of the present specification, the first sub-pixel may be a red (R) sub-pixel or a green (G) sub-pixel, and the second sub-pixel may be a blue (B) sub-pixel.

The display device according to various embodiments of the present specification may further include a circuit part between the substrate and the first organic insulating pattern and between the substrate and the second organic insulating pattern, in which the circuit part may include a first circuit part disposed in the first sub-pixel and electrically connected to the first anode electrode, and a second circuit part disposed in the second sub-pixel and electrically connected to the second anode electrode.

In the display device according to various embodiments of the present specification, the fine-sized sub-pixels can be manufactured using the patterning process using a photoresist, thereby improving the resolution of the display device.

In the display device according to various embodiments of the present specification, during the process of forming an organic insulating pattern, the height of the organic insulating pattern can vary depending on the width of the organic insulating pattern. By using such a feature, the heights of the organic insulating patterns disposed in the red (R) and green (G) pixel areas can be formed to be smaller than that of the organic insulating pattern disposed in the blue (B) pixel area. Accordingly, the steps can be formed between the organic light-emitting elements disposed in the pixel areas, and the size of each pixel area can be easily adjusted. By expanding the blue (B) pixel area, the color balance of the display device can be improved.

In the display device according to various embodiments of the present specification, by forming the blue (B) sub-pixel area in which degradation progresses relatively rapidly with an increased area, the lifetime of the display device can be extended, thereby achieving low power consumption.

However, effects obtainable from the present specification are not limited to the above-described effects, and other effects that are not mentioned will be able to be clearly understood by those skilled in the art to which the present specification pertains from the following description.

Although various embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of various embodiments is determined by the appended claims rather than detailed description. In addition, the meaning and scope of the claims and all changed or modified forms derived from the equivalent concept thereof should be construed as being included in the scope of various embodiments.

### DESCRIPTION OF REFERENCE NUMERALS

10: display device
100: substrate
200: circuit part
300: step layer
310: organic insulating pattern
350: planarization layer
400: anode electrode
500: auxiliary layer
600: light-emitting layer
700: insulating layer
800: cathode electrode
CT: contact hole

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate on which a first sub-pixel and a second sub-pixel are defined;
a plurality of first organic insulating patterns disposed over a region of the substrate corresponding to the first sub-pixel and having a first surface height;
a plurality of second organic insulating patterns disposed over a region of the substrate corresponding to the second sub-pixel and having a second surface height;
a first anode electrode on the plurality of first organic insulating patterns;
a second anode electrode on the plurality of second organic insulating patterns;
a first light-emitting layer on the first anode electrode;
a second light-emitting layer on the second anode electrode;
a cathode electrode on the first light-emitting layer and the second light-emitting layer; and
a circuit part between the substrate and the plurality of first organic insulating patterns and between the substrate and the plurality of second organic insulating patterns,
wherein the circuit part includes a first circuit part disposed in the first sub-pixel and electrically connected to the first anode electrode, and a second circuit part disposed in the second sub-pixel and electrically connected to the second anode electrode, and
wherein the second surface height is greater than the first surface height.

2. The display device of claim 1, further comprising a planarization layer which is present in spaces between adjacent first organic insulating patterns and spaces between adjacent second organic insulating patterns, wherein the plurality of first organic insulating patterns are disposed to be spaced apart from each other in a first direction, and the plurality of second organic insulating patterns are disposed to be spaced apart from each other in the first direction.

3. The display device of claim 1, wherein the plurality of first organic insulating patterns and the plurality of second organic insulating patterns extend in a direction away from the substrate and are then bent.

4. The display device of claim 3, wherein the plurality of first organic insulating patterns extend in a direction away from the substrate and then bent toward the substrate, and the plurality of second organic insulating patterns extend in the direction away from the substrate and are then bent in a direction parallel to the substrate.

5. The display device of claim 1, wherein widths of the plurality of first organic insulating patterns are smaller than widths of the plurality of second organic insulating patterns.

6. The display device of claim 1, wherein the first anode electrode is in direct contact with the plurality of first organic insulating patterns, and the second anode electrode is in direct contact with the plurality of second organic insulating patterns.

7. The display device of claim 1, wherein the first anode electrode is positioned below the second anode electrode.

8. The display device of claim 1, wherein the first light-emitting layer and the second light-emitting layer are separated.

9. The display device of claim 8, wherein side surfaces of the first light-emitting layer are in direct contact with the plurality of second organic insulating patterns.

10. The display device of claim 8, wherein the cathode electrode is in direct contact with side surfaces of the second light-emitting layer.

11. The display device of claim 8, further comprising auxiliary layers on the plurality of second organic insulating patterns.

12. The display device of claim 11, wherein the auxiliary layers are disposed on each of one side and the other side of the second anode electrode in a first direction.

13. The display device of claim 11, further comprising an insulating layer disposed between the auxiliary layers and the second anode electrode.

14. The display device of claim 13, wherein the cathode electrode is in direct contact with the insulating layer.

15. The display device of claim 13, wherein the first sub-pixel includes a first light-emitting area and a first non-light-emitting area around the first light-emitting area, the second sub-pixel includes a second light-emitting area and a second non-light-emitting area around the second light-emitting area, and the auxiliary layer and the insulating layer are disposed across the first non-light-emitting area and the second non-light-emitting area.

16. The display device of claim 11, wherein the cathode electrode is in direct contact with the auxiliary layers.

17. The display device of claim 1, wherein the first sub-pixel is a red (R) sub-pixel or a green (G) sub-pixel, and the second sub-pixel is a blue (B) sub-pixel.
